(19) United States
(12) Patent Application Publication
(10) Pub. No.: US 2006/0177601 A1
(43) Pub. Date: Aug. 10, 2006

(54) Method of forming a ruthenium thin film using a plasma enhanced atomic layer deposition apparatus and the method thereof

(76) Inventors: Hyung-Sang Park, Seoul (KR); Sang-Won Kang, Seoul (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/056,487

(22) Filed: Feb. 10, 2005

(51) Int. Cl. C23C 16/00

(52) U.S. Cl. 427/576; 427/250

(57) ABSTRACT

A method of depositing a ruthenium(Ru) thin film by using readily available ruthenium precursors such as Ru(CP)₂ and Ru(EtCP)₂, ammonia gas(NH₃) as a reactant gas or a purge gas or both, and a plasma enhanced atomic layer deposition(PEALD) apparatus and the method thereof, according to the present invention, is disclosed. Also a gas mixture of nitrogen gas(N₂) and hydrogen(H₂) is used as a reactant gas or a purge gas or both in addition to ammonia gas in depositing a ruthenium thin film according to the present invention. A ruthenium(Ru) thin film of high density, very pure, very smooth on the film surface and uniform is deposited even at the temperature of the reaction chamber below 400° C. using ammonia gas and a gas mixture of nitrogen gas and hydrogen gas, respectively, as a reactant gas under plasma.

### FIELD OF THE INVENTION

The present invention relates to a method of forming a ruthenium(Ru) thin film using a plasma enhanced atomic layer deposition(PEALD) apparatus and the method thereof.

### BACKGROUND ART

Recently, copper material is being widely used for interconnecting the semiconductor elements on a semiconductor chip, even though aluminum material has been primarily used for the same purpose. When copper is used for forming interconnecting conductors, copper material has a tendency of being diffused into the surrounding insulation material directly underneath and the sides of the copper wires over time, causing electrical leakage, thereby the characteristics of the electrical system of the interconnecting wires is deteriorated through the leakage. In order to reduce the diffusion of the copper material into the surrounding insulation material over time, it is necessary to form a diffusion barrier layer between a copper wire and the surrounding insulation material.

In forming copper wires, a set of processing steps called damascene technique is commonly used, in which after an insulation layer is formed, the areas in the insulation layer where the copper wires are to be deposited on are etched, and then the etched areas are filled with copper. A diffusion layer is deposited first on the insulation layer before a copper layer is deposited in order to isolate the copper layer from the insulation layer.

The copper layer in the unwanted areas in the insulation layer is removed typically by means of the chemical-mechanical polishing(CMP) process or by etching to leave only the desired copper conductors. Thereafter, the exposed surfaces of the copper conductors are covered with a capping layer and then the entire surface of the substrate is covered with another insulation layer to complete the formation of the desired copper conductors.

The diffusion barrier layer formed for this purpose is desirably to have the property of high uniformity and density. Some of the examples of commonly used diffusion barrier layers are Ta, TaN, TaSiN, TaCN, W, WN, WSiN, WNC, TiN, TiCN and TiSiN layers, and these barrier layers are generally formed by using sputtering technique. As the dimension of the semiconductor elements is becoming significantly tighter, however, it is desirable to form the diffusion barrier layer using atomic layer deposition(ALD) method, with which very conformal and dense thin films can be formed, thereby the requirements for forming diffusion barrier layers, where the line geometries are extremely tight, can be met.

Furthermore, in order to form a set of high quality copper conductors with low resistivity required for fabricating the next generation semiconductor devices, an adhesion layer with excellent adhesion property is also needed between the copper layer and the diffusion barrier layer formed by ALD method.

A ruthenium(Ru) thin film is known to have very low resistivity and excellent stability in a wide range of temperatures. In order to satisfy the requirements of low resistivity and high quality of adhesion characteristics described above, attempts have been made recently to improve the adhesion characteristics as well as the characteristics of the diffusion barrier layer with low resistivity by forming a ruthenium thin film as thin as several nanometers between the copper layer and the diffusion barrier layer.

There exist several methods of forming ruthenium thin films, i.e., sputtering method based upon physical vapor deposition(PVD) method, chemical vapor deposition(CVD) method and atomic layer deposition(ALD) method.

Sputtering method and CVD method have the following drawbacks in forming extremely small semiconductor devices to meet the requirements for the future generation of semiconductor integrated circuits.

A ruthenium thin film deposited by using sputtering method has the characteristics of high degree of purity, uniformity and density, but it has a drawback of having poor step coverage, thereby it is not well suited for forming a thin film requiring good step coverage as the width of the integrated circuit patterns is getting tighter and the depth of the trenches is becoming deeper in forming extremely small semiconductor elements. Therefore, the ruthenium thin films formed by sputtering method has limitations as a diffusion barrier layer for blocking the diffusion of copper material into the neighboring insulation layer and as an adhesion layer between the copper layer and the diffusion layer as well as other applications such as the electrodes of the storage capacitors in dynamic random access memories(DRAMs).

In comparison with the sputtering method described above, CVD method of forming ruthenium thin films has better step coverage, but the CVD method has also a drawback of difficulty in controlling the thickness of the thin films of only several nanometers thick required in forming extremely small integrated circuit elements.

However, ALD method of depositing ruthenium thin films has excellent step coverage and is well suited for forming extremely dense integrated circuits. Kim, Younsoo, [U.S. Pat. No. 6,800,542, “METHOD FOR FABRICATING RUTHENIUM THIN LAYER”] disclosed a thermal ALD method for depositing ruthenium thin films without plasma, wherein the ruthenium precursors of the form Ru(X)n, where n=2 or 3, and a nitrogen-containing reductive reaction gas are used, where X represents an anionic ligand. U.S. Pat. No. 6,800,542 also suggests various potential candidates for ruthenium precursors and reaction gases. However, most of the ruthenium precursors suggested here are not readily available, and furthermore, U.S. Pat. No. 6,800,542 does not disclose any noticeable results other than that a highly pure ruthenium layer with less amount of impurity can be deposited, thereby no data are available to compare with the results of the present invention

For the CVD method of forming ruthenium thin films, the ruthenium precursors of the form Ru(X)n (n is an integer) with oxygen gas(O₂) as a reaction gas, where X is a cyclopentadienyl(Cp) ligand or an alkylcyclopentadienyl ligand, and also bis(cyclopentadienyl)ruthenium[Ru(Cp)₂] and bis(ethylcyclopentadienyl)ruthenium[Ru(EtCp)₂] are used. These ruthenium precursors are readily available and can also be used in forming ruthenium thin films by using thermal ALD method with oxygen gas(O₂) as a reaction gas.

However, CVD method and thermal ALD method have a common drawback. Oxygen gas(O₂) used as a reactant gas causes oxidization of the prior-deposited conductive layers, mostly the conductors prior-deposited directly underneath and the prior-deposited neighboring conductors, through which the surface boundaries between the conductive layers make electrical contacts each other, thereby the contact resistance increases. As a result, the effective resistance of the entire interconnecting wiring system increases, thereby the electrical characteristics of the entire interconnecting wiring system which is part of BEOL(Back End Of Line) metallization process deteriorates and it makes the deposition method of using oxygen gas(O₂) as a reactant gas unsuitable to use for fabricating extremely high density integrated circuits. This is why oxygen gas(O₂) is not necessarily a preferred reactant gas.

For the BEOL metallization process applications, the required characteristics of a ruthenium thin film are high conductivity, high degree of purity, having certain preferred orientation of its crystal structure, smooth surface and excellent adhesion property.

The object of the present invention is to disclose a method of depositing ruthenium thin films that overcome the deficiencies described above and thus suitable for forming an interconnecting wiring system in fabricating extremely high density semiconductor integrated circuits.

### BRIEF DESCRIPTION OF THE DRAWINGS

FIG. 1 is a process flowchart of forming a ruthenium thin film according to the present invention.

FIG. 2 is the first example of a ruthenium thin film deposition process cycle using a ruthenium precursor, a purge gas, a reactant gas and plasma, and by using a PEALD method.

FIG. 3 is the second example of a ruthenium thin film deposition process cycle using a ruthenium precursor, a reactant gas and plasma, and by using a PEALD method.

FIG. 4 is the third example of a ruthenium thin film deposition process cycle using a ruthenium precursor, a purge gas and a plasma-activated reactant gas, and by using a PEALD method.

FIG. 5 is the fourth example of a ruthenium thin film deposition process cycle using a ruthenium precursor gas and plasma-activated reaction gas, and by using a PEALD method.

FIG. 6 is a graph showing thicknesses of the ruthenium thin films deposited on the surface of a substrate as a function of the number of repetitions of the deposition cycles, where the ruthenium thin films are deposited, respectively, by both conventional thermal ALD method and by the PEALD method according to the present invention.

FIG. 7 is a graph showing the results of the analyses of X-ray Diffraction of the crystal structures of the ruthenium thin films deposited, respectively, by conventional thermal ALD method and also by the PEALD method according to the present invention.

FIG. 8A is an image of surface roughness of a ruthenium thin film deposited on the surface of a substrate by conventional thermal ALD method. The image is taken with an Atomic Force Microscope (AFM) and the measured root-mean-square(rms) roughness of the ruthenium thin film surface is 3.1 nm. FIG. 8B is an image of surface roughness of a ruthenium thin film deposited on the surface of a substrate by the PEALD method according to the present invention. The image is taken with an Atomic Force Microscope(AFM) and the roughness of the ruthenium thin film surface is measured at 0.7 nm in rms.

### DISCLOSURE OF THE INVENTION

The present invention discloses a method of depositing ruthenium(Ru) thin films using a ruthenium precursor as a source gas, ammonia gas(NH₃) or a gas mixture of nitrogen gas(N₂) and hydrogen gas(H₂) as a reactant gas and optionally a purge gas, and by using a plasma enhanced atomic layer deposition(PEALD) apparatus and the method thereof, where neither ammonia gas(NH₃) nor the gas mixture of nitrogen gas(N₂) and hydrogen gas(H₂), without activation by plasma, reacts with the ruthenium precursor gas at the temperature below 400° C. Further, according to the present invention, plasma is generated in the reaction chamber while either the reaction chamber is filled with the reactant gas or the reactant gas is continuously flown through the reaction chamber so that the reaction between the ruthenium precursor adsorbed onto the surface of s substrate and the reactant gas activated by plasma takes place fully under the condition that the substrate is completely surrounded by the reactant gas during the entire plasma generation period when plasma is applied in the reaction chamber at the temperature below 400° C.

One of the objects of the present invention is to deposit ruthenium thin films well suited for forming diffusion barrier layers as well as adhesion layers providing good adhesion between the copper layers and the conventional barrier layer materials such as TaN, Ta, TaSiN, TaCN, WN, W, WSiN, WNC, TiN, TiCN and TiSiN. Furthermore, ruthenium thin films have numerous other applications such as the electrodes in high k capacitors for storing data in dynamic random access memories(DRAMs).

The present invention discloses a method of depositing a ruthenium thin film at the temperature below 400° C. using a ruthenium precursor of the form Ru(XaXb) in gaseous state, ammonia gas(NH₃) as a reactant gas, optionally a purge gas and activating the reactant gas with plasma, and by using a PEALD apparatus and the method thereof, where the oxidation problem aforementioned is alleviated by using ammonia gas as a reactant gas instead of oxygen gas(O₂) as described previously.

The present invention also discloses a method of depositing a ruthenium thin film at the temperature below 400° C. using a ruthenium precursor of the form Ru(XaXb) in gaseous state, a gas mixture of nitrogen gas(N₂) and hydrogen gas(H₂) as a reactant gas, optionally a purge gas and activating the reactant gas with plasma, and by using a PEALD apparatus and the method thereof, where the oxidation problem aforementioned is alleviated by using the gas mixture of nitrogen gas(N₂) and hydrogen gas(H₂) as a reactant gas instead of oxygen gas(O₂) as described previously.

The present invention discloses a method of depositing a ruthenium thin film using a ruthenium precursor gas and optionally a purge gas, and supplying plasma-activated ammonia gas(NH₃) as a reactant gas, and by using a PEALD apparatus and the method thereof.

The present invention also discloses a method of depositing a ruthenium thin film using a ruthenium precursor gas and supplying plasma-activated gas mixture of nitrogen gas(N₂) and hydrogen gas(H₂) as a reactant gas, and by using a PEALD apparatus and the method thereof.

According to the present invention, the ruthenium thin films deposited suppress oxidation of the prior-deposited thin films because the present invention does not use oxygen gas(O₂) as a reactant gas, thereby the ruthenium thin films deposited according to the present invention provide electrically good conducting layers as well as physically good adhesion layers.

Also, according to the present invention, the ruthenium thin film deposited by means of the processes disclosed in the present invention has improved surface roughness, thereby the ruthenium thin film provide very thin continuous layer which has a smooth interface with the copper layer, resulting in low surface resistivity due to reduced electron scattering at the interface.

### DETAILED DESCRIPTION OF THE PRESENT INVENTION

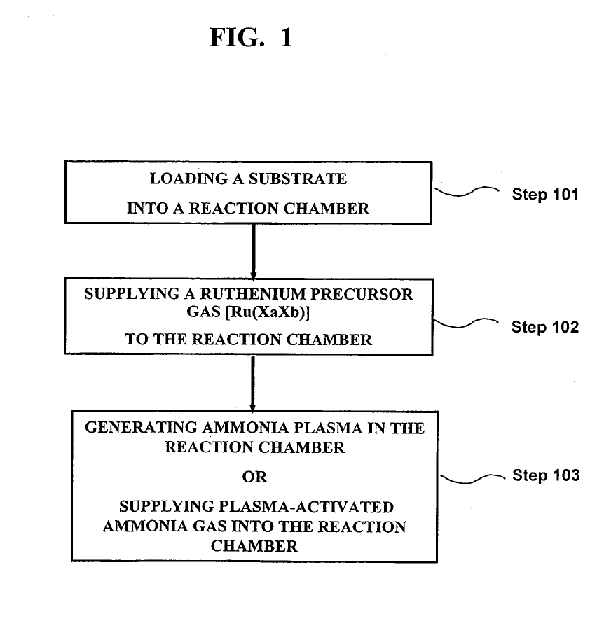

FIG. 1 is a flowchart illustrating the process steps described above for depositing ruthenium thin films on the surface of a substrate according to the present invention, in which after loading a substrate into a reaction chamber in Step 101, a ruthenium precursor of the form Ru(XaXb) is supplied to the reaction chamber in Step 102 so that the ruthenium precursor gas is adsorbed onto the surface of the substrate, an inert gas(not shown) is optionally supplied to the reaction chamber to purge the reaction chamber, and ammonia(NH₃) plasma is generated in the reaction chamber or plasma-activated ammonia gas is supplied into the reaction chamber in Step 103 so that a reaction between the ruthenium precursor adsorbed onto the surface of the substrate and the ammonia plasma gas or the plasma-activated ammonia gas takes place on the surface of the substrate in the reaction chamber, thereby a ruthenium thin film is deposited on the surface of the substrate. The reaction chamber is optionally purged by supplying an inert gas(not shown). Here, the gas mixture plasma of nitrogen gas(N₂) and hydrogen gas(H₂) and the plasma-activated gas mixture of nitrogen gas(N₂) and hydrogen gas(H₂) are also used(not shown) instead of the ammonia(NH₃) plasma and the plasma-activated ammonia gas.

For clarification, “generating ammonia plasma” or “ammonia plasma is generated” or the like statements mean that “ammonia gas is supplied and then plasma is generated in the reaction chamber”, and “plasma-activated ammonia gas” means “the ammonia gas activated by plasma outside the reaction chamber”. Likewise, “generating mixed gas plasma of nitrogen gas(N₂) and hydrogen gas(H₂)” or “mixed gas plasma is generated” or the like statements mean that “a mixed gas of nitrogen gas(N₂) and hydrogen gas(H₂) is supplied and then plasma is generated in the reaction chamber”, and “plasma-activated gas mixture of . . . ” or “plasma-activated mixed gas of . . . ” mean that “the gas mixture of . . . activated by plasma outside the reaction chamber”.

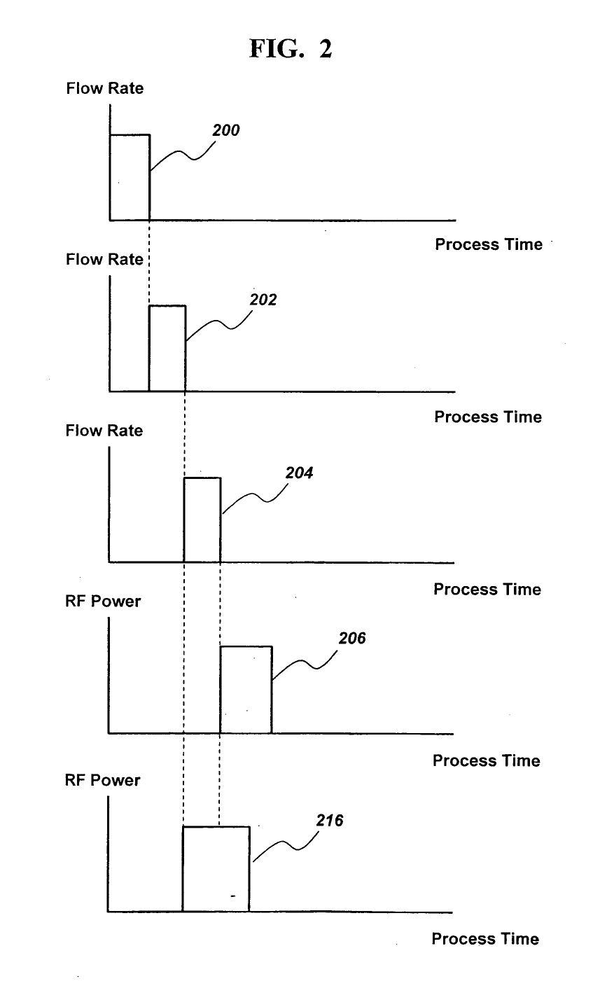

According to the present invention, in order to deposit a ruthenium thin film on the surface of a substrate in a reaction chamber by using a PEALD apparatus and the method thereof, referring to FIG. 2, a ruthenium precursor gas 200 is supplied to the reaction chamber so that the ruthenium precursor gas is adsorbed onto the surface of the substrate, an inert gas 202 is supplied to the reaction chamber to purge the reaction chamber, ammonia gas(NH₃) 204 is supplied to the reaction chamber and then plasma 206 is generated in the reaction chamber to activate the ammonia gas(NH₃) 204 so that a reaction between the ruthenium precursor gas and the ammonia gas activated by plasma takes place, thereby a ruthenium thin film is deposited on the surface of the substrate. Optionally, the reaction chamber is purged(not shown) using an inert gas after the plasma generation period 206, where ammonia gas can be used as a purge gas at the temperature below 400° C. in the reaction chamber when the ammonia gas is not activated by plasma, since ammonia gas without activation by plasma does not react with the ruthenium precursor gas below 400° C.

According to another aspect of the present invention, referring to FIG. 2, a ruthenium thin film is deposited on the surface of a substrate in a reaction chamber using a PEALD apparatus and the method thereof, by supplying a ruthenium precursor gas 200 to the reaction chamber so that the ruthenium gas is adsorbed onto the surface of a substrate, an inert gas 202 is supplied to the reaction chamber to purge the reaction chamber, ammonia gas(NH₃) 204 is supplied to the reaction chamber and at the same time plasma 216 is generated in the reaction chamber in synchronization with the ammonia gas supply period 204 so that the reaction between the ruthenium precursor gas and the ammonia gas activated by plasma takes place in the reaction chamber, thereby a ruthenium thin film is deposited on the surface of the substrate, where the start time of plasma generation period 216 can occur after the start time of the supply period of the ammonia gas 204 so that the purge gas 202 in the reaction chamber is purged by supplying ammonia gas 204 before the plasma generation period 216 is started(not shown), and also the end time of the plasma generation period 216 can occur after the end time of the ammonia gas supply period 204 as illustrated in FIG. 2 or the end time of the plasma generation period 216 can occur before the end time of the ammonia gas supply period 204. Optionally, the reaction chamber is purged(not shown) after each of the plasma generation periods 206 or 216, respectively.

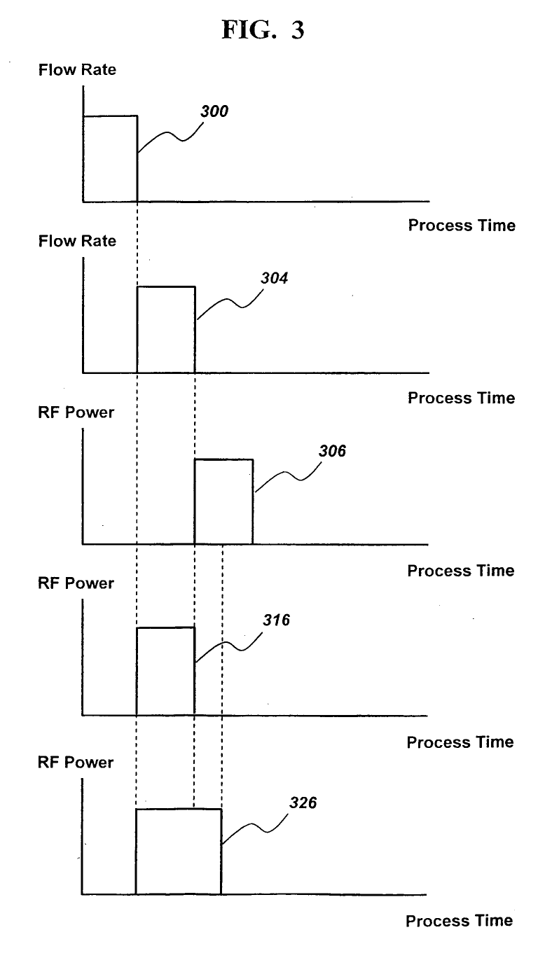

According to another aspect of the present invention, referring to FIG. 3, in order to deposit a ruthenium thin film on the surface of a substrate in a reaction chamber by using a PEALD apparatus and the method thereof, a ruthenium precursor gas 300 is supplied to the reaction chamber in the PEALD apparatus so that the ruthenium precursor gas is adsorbed onto the surface of the substrate, ammonia gas 304 is supplied into the reaction chamber to purge the ruthenium precursor gas in the reaction chamber and to fill the reaction chamber with ammonia gas 304, and plasma 306 is generated in the reaction chamber so that a reaction between the ruthenium precursor gas and the ammonia gas activated by plasma takes place in the reaction chamber, thereby a ruthenium thin film is deposited on the surface of the substrate. Optionally, the reaction chamber is purged(not shown) by supplying an inert gas after the plasma generation period 306.

According to another aspect of the present invention, referring to FIG. 3, in order to deposit a ruthenium thin film on the surface of a substrate by using a PEALD apparatus and the method thereof, a ruthenium precursor gas 300 is supplied to the reaction chamber so that the ruthenium precursor gas is adsorbed onto the surface of a substrate, ammonia gas 304 is supplied to the reaction chamber and at the same time plasma pulse 316 is generated in the reaction chamber in synchronization with the ammonia gas supply period 304 so that the reaction between the ruthenium precursor gas and the ammonia gas activated by plasma takes place in the reaction chamber, thereby a ruthenium thin film is deposited on the surface of the substrate, where the start time of the plasma generation period 316 can occur after the start time of the supply period of the ammonia gas 304 so that the ruthenium precursor gas un-adsorbed onto the surface of the substrate and remaining in the reaction chamber space is purged by the ammonia gas 304 before plasma 316 is generated(not shown), and the end time of the plasma generation period 316 can occur after the end time of the ammonia gas supply period 304 as shown as 326 in FIG. 3 or before the end time of the ammonia gas supply period 304(not shown). Optionally, the reaction chamber is purged(not shown) after each of the plasma generation periods 316 and 326, respectively. Here, according to the present invention, the flow of the ammonia gas before or after the plasma generation period 316 plays a role of purging the reaction chamber, since ammonia gas does not practically react with the ruthenium precursor gas below 400° C. without activation by plasma as described previously.

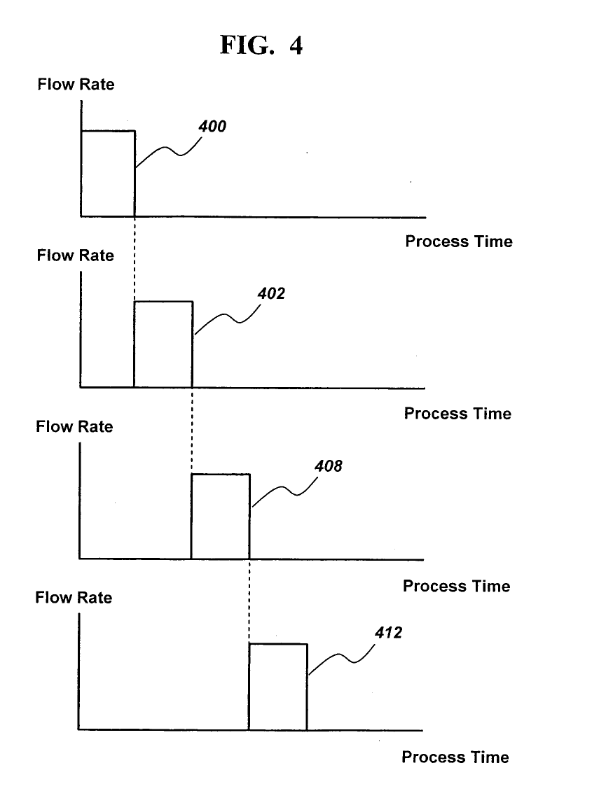

According to another aspect of the present invention, referring to FIG. 4, in order to deposit a ruthenium thin film on the surface of a substrate in a reaction chamber by using a PEALD apparatus and the method thereof, a ruthenium precursor gas 400 is supplied to the reaction chamber so that the ruthenium precursor gas is adsorbed onto the surface of the substrate, the reaction chamber is purged by using an inert gas 402, the plasma-activated ammonia gas 408 is supplied into the reaction chamber so that a reaction between the ruthenium precursor and the plasma-activated ammonia gas takes place in the reaction chamber, thereby a ruthenium thin film is deposited on the surface of the substrate. Optionally, the reaction chamber is purged using an inert gas 412 after the plasma-activated ammonia gas supply period 408.

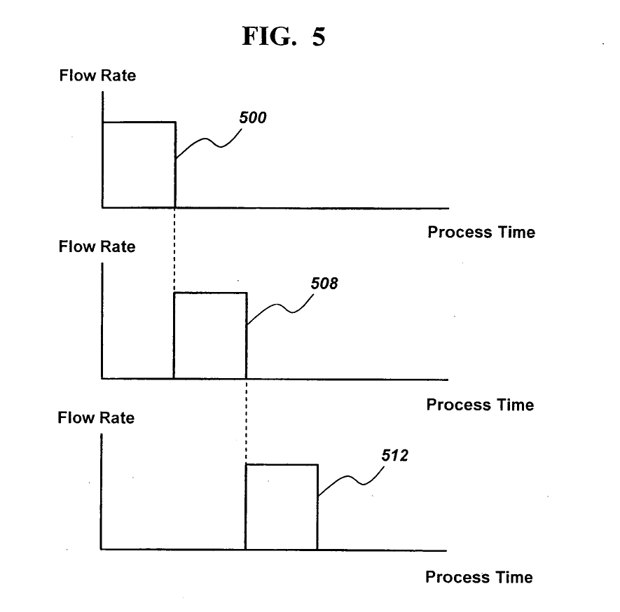

According to another aspect of the present invention, referring to FIG. 5, in order to deposit a ruthenium thin film on the surface of a substrate in a reaction chamber by using a PEALD apparatus and the method thereof, a ruthenium precursor gas 500 is supplied to the reaction chamber so that the ruthenium precursor gas is adsorbed onto the surface of the substrate, the plasma-activated ammonia gas 508 is supplied into the reaction chamber so that a reaction between the ruthenium precursor and the plasma-activated ammonia gas takes place in the reaction chamber, thereby a ruthenium thin film is deposited on the surface of the substrate. Optionally, the reaction chamber is purged using an inert gas 512 after the plasma-activated ammonia gas supply period 508.

According to the present invention, in order to deposit a ruthenium thin film on the surface of a substrate in a reaction chamber by using a PEALD apparatus and the method thereof, referring to FIG. 2, a ruthenium precursor gas 200 is supplied to the reaction chamber so that the ruthenium precursor gas is adsorbed onto the surface of the substrate, ammonia gas(NH₃) 202′(not shown) as an inert gas 202 is supplied to the reaction chamber to purge the ruthenium precursor gas un-adsorbed onto the surface of the substrate and remaining in the reaction chamber space and, while the ammonia gas(NH₃) 202′ is continuously flown through(shown as 204 in FIG. 2) the reaction chamber, plasma 216′ in place of the plasma generation period 216 is generated in the reaction chamber to activate the ammonia gas 202′ and 204′ (shown as 204 in FIG. 2) by plasma 216′ so that a reaction between the ruthenium precursor adsorbed onto the surface of the substrate and the ammonia gas 202′ and 204′ activated by plasma 216′ takes place, thereby a ruthenium thin film is deposited on the surface of the substrate, where the start time point for the plasma generation 216′ can occur before or after the start time point of the ammonia gas supply period 204′ depending upon how quickly the ruthenium precursor gas un-adsorbed and remaining in the reaction chamber space is purged by the ammonia gas 202′. Optionally, the reaction chamber is purged(not shown) after the plasma generation period 216′ by either continuously flowing ammonia gas or flowing an inert gas, where the ammonia gas without activation by plasma can be used as a purge gas at the temperature of the reaction chamber below 400° C,, since ammonia gas without activation by plasma does not react with the ruthenium precursor gas below 400° C.

According to another aspect of the present invention, in order to deposit a ruthenium thin film on the surface of a substrate in a reaction chamber by using a PEALD apparatus and the method thereof, referring to FIG. 2, a ruthenium precursor gas 200 is supplied to the reaction chamber so that the ruthenium precursor gas is adsorbed onto the surface of the substrate, an inert gas 202 is supplied to the reaction chamber to purge the reaction chamber, a gas mixture of nitrogen gas(N₂) and hydrogen gas(H₂) 204″(not shown) in place of ammonia gas 204 is supplied to the reaction chamber and then plasma 206″(not shown) is generated in the reaction chamber to activate the gas mixture of nitrogen gas(N₂) and hydrogen gas(H₂) 204″ so that a reaction between the ruthenium precursor and the gas mixture of nitrogen gas and hydrogen gas activated by plasma takes place, thereby a ruthenium thin film is deposited on the surface of the substrate. Optionally, the reaction chamber is purged(not shown) using an inert gas after the plasma generation period 206″, where the gas mixture of nitrogen gas(N₂) and hydrogen gas(H₂) can be used as a purge gas at the temperature of the reaction chamber below 400° C. when the gas mixture of nitrogen gas and hydrogen gas is not activated by plasma, since the gas mixture of nitrogen gas and hydrogen gas without activation by plasma does not react with the ruthenium precursor gas below 400° C.

According to another aspect of the present invention, referring to FIG. 2, a ruthenium thin film is deposited on the surface of a substrate in a reaction chamber using a PEALD apparatus and the method thereof, by supplying a ruthenium precursor gas 200 to the reaction chamber so that the ruthenium precursor gas is adsorbed onto the surface of a substrate, an inert gas 202 is supplied to the reaction chamber to purge the reaction chamber, a gas mixture of nitrogen gas(N₂) and hydrogen gas(H₂) 204′″(not shown) in place of ammonia gas 204 is supplied to the reaction chamber and at the same time plasma 216′″ is generated in the reaction chamber in synchronization with the gas mixture of nitrogen gas(N₂) and hydrogen gas(H₂) supply period 204′″(not shown) so that the reaction between the ruthenium precursor and the gas mixture of nitrogen gas and hydrogen gas activated by plasma takes place in the reaction chamber, thereby a ruthenium thin film is deposited on the surface of the substrate, where the start time of the plasma generation period 216′″(not shown) can occur after the start time of the supply period of the gas mixture 204′″ of nitrogen gas and hydrogen gas so that the purge gas 202′″(not shown) in the reaction chamber is purged by the gas mixture of nitrogen gas(N₂) and hydrogen gas(H₂) 204′″ before the plasma generation period 216′″ is started(not shown), and also the end time of the plasma generation period 216′″ can occur after the end time of the gas mixture of nitrogen gas(N₂) and hydrogen gas(H₂) supply period 204′″(not shown) in place of the ammonia gas supply period 204 as illustrated in FIG. 2 or the end time of the plasma generation period 216′″ can occur before the end time of the gas mixture of nitrogen gas(N₂) and hydrogen gas(H₂) supply period 204′″ instead the ammonia gas supply period 204. Optionally, the reaction chamber is purged(not shown) after each of the plasma generation period 216′″(not shown).

According to another aspect of the present invention, referring to FIG. 3, in order to deposit a ruthenium thin film on the surface of a substrate in a reaction chamber by using a PEALD apparatus and the method thereof, a ruthenium precursor gas 300 is supplied to the reaction chamber in the PEALD apparatus so that the ruthenium precursor gas is adsorbed onto the surface of the substrate, a gas mixture of nitrogen gas(N₂) and hydrogen gas(H₂) 304′(not shown) instead of ammonia gas 304 is supplied into the reaction chamber to purge the ruthenium precursor gas in the reaction chamber and to fill the reaction chamber with the gas mixture of nitrogen gas(N₂) and hydrogen gas(H₂) 304′, and plasma 306′(not shown) is generated in the reaction chamber so that a reaction between the ruthenium precursor gas and the gas mixture of nitrogen gas and hydrogen gas activated by plasma takes place in the reaction chamber, thereby a ruthenium thin film is deposited on the surface of the substrate. Optionally, the reaction chamber is purged(not shown) by using an inert gas after the plasma generation period 306′.

According to another aspect of the present invention, referring to FIG. 3, in order to deposit a ruthenium thin film on the surface of a substrate by using a PEALD apparatus and the method thereof, a ruthenium precursor gas 300 is supplied to the reaction chamber so that the ruthenium precursor gas is adsorbed onto the surface of a substrate, a gas mixture of nitrogen gas(N₂) and hydrogen gas(H₂) 304″(not shown) is supplied to the reaction chamber and at the same time plasma pulse 316″(not shown) is generated in the reaction chamber in synchronization with the gas mixture of nitrogen gas(N₂) and hydrogen gas(N₂) supply period 304″ so that the reaction between the ruthenium precursor gas and the gas mixture of nitrogen gas and hydrogen gas activated by plasma takes place in the reaction chamber, thereby a ruthenium thin film is deposited on the surface of the substrate, where the start time of the plasma generation period 316″ can occur after the start time of the supply period of the gas mixture of nitrogen gas and hydrogen gas 304″ so that the ruthenium precursor gas un-adsorbed onto the surface of the substrate and remaining in the reaction chamber space is purged by the gas mixture of nitrogen gas(N₂) and hydrogen gas(H₂) 304″ before plasma is generated 316″(not shown), and the end time of the plasma generation period 316″ can occur after the end time of the gas mixture of nitrogen gas(N₂) and hydrogen gas(H₂) supply period 304″(not shown) in place of the ammonia gas supply period 304 as shown in FIG. 3 as 326″(not shown) or before the end time of the gas mixture of nitrogen gas(N₂) and hydrogen gas(H₂) supply period 304″(not shown). Optionally, the reaction chamber is purged(not shown) after each of the plasma generations, 316″ and 326″, respectively. Here, according to the present invention, the flow of the gas mixture of nitrogen gas and hydrogen gas before or after the plasma generation period 316″ plays a role of purging the reaction chamber, since the gas mixture of nitrogen gas(N₂) and hydrogen gas(H₂) does not practically react with the ruthenium precursor gas below 400° C. without activation by plasma as described previously.

According to another aspect of the present invention, referring to FIG. 4, in order to deposit a ruthenium thin film on the surface of a substrate in a reaction chamber by using a PEALD apparatus and the method thereof, a ruthenium precursor gas 400 is supplied to the reaction chamber so that the ruthenium precursor gas is adsorbed onto the surface of the substrate, the reaction chamber is purged by using an inert gas 402, the plasma-activated gas mixture of nitrogen gas and hydrogen gas 408′(not shown) in place of the plasma-activated ammonia gas 408 is supplied into the reaction chamber so that a reaction between the ruthenium precursor and the plasma-activated gas mixture of nitrogen gas and hydrogen gas takes place in the reaction chamber, thereby a ruthenium thin film is deposited on the surface of the substrate. Optionally, the reaction chamber is purged using an inert gas 412′(not shown) after the plasma-activated gas mixture of nitrogen gas and hydrogen gas supply period 408′(not shown).

According to another aspect of the present invention, referring to FIG. 5, in order to deposit a ruthenium thin film on the surface of a substrate in a reaction chamber by using a PEALD apparatus and the method thereof, a ruthenium precursor gas 500 is supplied to the reaction chamber so that the ruthenium precursor gas is adsorbed onto the surface of the substrate, the plasma-activated gas mixture of nitrogen gas and hydrogen gas 508′(not shown) is supplied into the reaction chamber so that a reaction between the ruthenium precursor and the plasma-activated gas mixture of nitrogen gas and hydrogen gas 508′(not shown) takes place in the reaction chamber, thereby a ruthenium thin film is deposited on the surface of the substrate. Optionally, the reaction chamber is purged using an inert gas 512′(not shown) after the plasma-activated gas mixture of nitrogen gas and hydrogen gas supply period 508′(not shown).

According to the present invention, in order to deposit a ruthenium thin film on the surface of a substrate in a reaction chamber by using a PEALD apparatus and the method thereof, referring to FIG. 2, a ruthenium precursor gas 200 is supplied to the reaction chamber so that the ruthenium precursor gas is adsorbed onto the surface of the substrate, a gas mixture of nitrogen gas(N₂) and hydrogen gas(H₂) 202″″(not shown) as an inert gas 202 is supplied to the reaction chamber to purge the ruthenium precursor gas un-adsorbed onto the surface of the substrate and remaining in the reaction chamber space and, while the gas mixture of nitrogen gas(N₂) and hydrogen gas(H₂) 202″″(not shown) is continuously flown through(shown as 204 in FIG. 2) the reaction chamber, plasma 216″″ in place of the plasma generation period 216 is generated in the reaction chamber to activate the gas mixture of nitrogen gas(N₂) and hydrogen gas(H₂) 202″″ and 204″″(not shown but shown as 204 in FIG. 2) by plasma 216″″ so that a reaction between the ruthenium precursor gas adsorbed onto the surface of the substrate and the gas mixture of nitrogen gas(N₂) and hydrogen gas(H₂) 202″″ and 204″″ activated by plasma 216″″ takes place, thereby a ruthenium thin film is deposited on the surface of the substrate, where the starting time point for the plasma generation 216″″ can occur before or after the start time point of the gas mixture of nitrogen gas(N₂) and hydrogen gas(H₂) supply period 204″″ depending upon how quickly the ruthenium precursor gas remaining in the reaction chamber space is purged by the gas mixture of nitrogen gas(N₂) and hydrogen gas(H₂) 202″″. Optionally, the reaction chamber is purged(not shown) after the plasma generation period 216″″ by either continuously flowing the gas mixture of nitrogen gas(N₂) and hydrogen gas(H₂) or flowing an inert gas, where the gas mixture of nitrogen gas(N₂) and hydrogen gas(H₂) without activation by plasma can be used as a purge gas at the temperature of the reaction chamber below 400° C., since the gas mixture of nitrogen gas(N₂) and hydrogen gas(H₂) without activation by plasma does not react with the ruthenium precursor gas below 400° C.

According to the present invention, one of the readily available ruthenium precursors suitable for use with the PEALD apparatus and the method thereof is of the form Ru(XaXb), where Xa and Xb are cyclopentadienyl(Cp) or alkylcyclopendadienyl of which alkyl group having one to three carbon atoms. More specifically, Xa and Xb are, respectively, any one of cyclopentadienyl(Cp), methylcyclopentadienyl(MeCp), ethylcyclopentadienyl(EtCp) and isopropylcyclopentadienyl(i-PrCp). When Xa=Xb=X, the ruthenium precursor form is given as Ru(X)₂. Some of the examples are bis(cyclopentadienyl)ruthenium[Ru(Cp)₂], bis(ethylcyclopentadienyl)ruthenium[Ru(EtCp)₂] and (methylcyclopentadienyl)(ethylcyclopentadienyl) ruthenium[Ru(MeCp)(EtCp)].

In order to form a ruthenium thin film to a desired thickness, the deposition processes described above according to the present inventions are repeated as necessary.

In the embodiments presented below, the ruthenium precursor Ru(EtCp)₂ is used as a ruthenium precursor. As a reaction gas, ammonia gas(NH₃) is used, where the ammonia gas does not react with the source gas, ruthenium precursor [Ru(EtCp)₂], at the temperature below 400° C. when the ammonia gas is not activated by plasma. However, the plasma-activated ammonia gas reacts effectively with the ruthenium precursor [Ru(EtCp)₂] even at a low temperature between 100° C. and 400° C., thereby a ruthenium thin film is deposited on the surface of a substrate at the temperature in the range from 100° C. to 400° C.

In the embodiments presented below, according to the present invention, a gas mixture of nitrogen gas(N₂) and hydrogen gas(H₂) is also used as a reaction gas in place of ammonia gas(NH₃), where the gas mixture of nitrogen gas and hydrogen gas activated by plasma exhibits a similar reactivity to the ruthenium precursor as the ammonia gas activated by plasma.

The present invention discloses a method of depositing a ruthenium thin film on a substrate using a PEALD apparatus and the method thereof. One example of such PEALD apparatus is disclosed in the Korean Patent Application No. 2001-0046802 [Lee, C. S., et al., “A Plasma Enhanced Atomic Layer Deposition Apparatus and A Method of Forming A Thin Film Using the Same”, or alternatively, Lee, C. S., et al., WO 03/023835, “Plasma Enhanced Atomic Layer Deposition (PEALD) Equipment and Method of Forming a Conducting Thin Film Using The Same Thereof”].

### BEST MODE FOR CARRYING OUT THE PRESENT INVENTION

Six exemplary embodiments of carrying out the method of depositing a ruthenium thin film according to the present invention are presented below.

In order to deposit a ruthenium thin film by using a PEALD apparatus and the method thereof, a substrate is loaded into a reaction chamber, the temperature inside the reaction chamber is maintained at a temperature in the range from 100° C. to 400° C., an inert gas is supplied into the reaction chamber to stabilize the reaction chamber pressure at the pressure level between 0.01 and 50 torr.

### EMBODIMENT 1

After the preparation steps described above, referring to FIG. 2, the ruthenium precursor Ru(EtCp)₂ in gaseous state 200 is supplied into the reaction chamber for the time duration between 0.02 and 20 seconds, thereby the ruthenium precursor gas is adsorbed onto the surface of the substrate. The ruthenium precursor gas un-adsorbed and remaining in the reaction chamber space is purged by flowing an inert gas 202 for the time duration between 0.1 and 10 seconds, ammonia gas(NH3) as a reactant gas 204 is supplied into the reaction chamber for the time duration between 0.02 and 10 seconds, plasma 206 is generated in the reaction chamber by applying RF power in the reaction chamber for the time duration between 0.02 and 10 seconds so that a ruthenium thin film is deposited on the surface of the substrate, and an inert gas is supplied(not shown) to the reaction chamber to purge the reaction chamber. The above steps are repeated until a ruthenium film layer to a desired thickness is formed.

### EMBODIMENT 2

After following the preparation steps described above, referring to FIG. 2, the ruthenium precursor Ru(EtCp)₂ 200 in a gaseous state is supplied into the reaction chamber for the time duration between 0.02 and 20 seconds, ammonia gas 202′ is supplied into the reaction chamber for the time duration between 0.1 and 10 seconds in order to purge the ruthenium precursor gas un-adsorbed onto the surface of the substrate and remaining in the reaction chamber space, and while ammonia gas 204′ is continuously flown through the reaction chamber, plasma is generated 216′ in the reaction chamber by applying RF power in the reaction chamber for the duration between 0.02 and 10 seconds to deposit a ruthenium thin film on the surface of the substrate. After the plasma generation period 216′, an inert gas is supplied(not shown) to the reaction chamber to purge the reaction chamber. Alternatively, ammonia gas(NH₃) is also used for purging the reaction chamber after the plasma generation period 216′. The above process steps are repeated until a ruthenium thin film is formed to a desired thickness.

### EMBODIMENT 3

After following the preparation steps described above, a gas mixture of nitrogen gas(N₂) and hydrogen gas(H₂) is used in place of ammonia gas(NH₃) as in Embodiment 1.

The gas mixture of nitrogen gas and hydrogen gas activated by plasma behaves very similarly to the ammonia gas activated by plasma, wherein the gas mixture of nitrogen gas and hydrogen gas does not react with the ruthenium precursor at the temperature lower than 400° C. without activation by plasma, thereby such gas mixture, when activated by plasma, is used as a reactant gas in combination with the ruthenium precursor according to the present invention, and also such gas mixture without activation by plasma is used as a purge gas.

In this exemplary embodiment, the remaining process conditions used for depositing a ruthenium thin film are the same as the process conditions for Embodiment 1 above.

After following the preparation steps described above, referring to FIG. 2, the ruthenium precursor Ru(EtCp)₂ in gaseous state 200 is supplied into the reaction chamber for the time duration between 0.02 and 20 seconds, thereby the ruthenium precursor gas is adsorbed onto the surface of the substrate. The ruthenium precursor gas un-adsorbed and remaining in the reaction chamber space is purged by flowing an inert gas 202 for the time duration between 0.1 and 10 seconds, a gas mixture of nitrogen gas(N₂) and hydrogen gas(H₂) as a reactant gas 204″ is supplied into the reaction chamber for the time duration between 0.02 and 10 seconds, plasma 206″ is generated in the reaction chamber by applying RF power in the reaction chamber for the time duration between 0.02 and 10 seconds so that a ruthenium thin film is deposited on the surface of the substrate, and an inert gas is supplied(not shown) to the reaction chamber to purge the reaction chamber. The above steps are repeated until a ruthenium film layer to a desired thickness is formed.

### EMBODIMENT 4

After following the preparation steps described above, referring to FIG. 2, the ruthenium precursor Ru(EtCp)₂ 200 in a gaseous state is supplied into the reaction chamber for the time duration between 0.02 and 20 seconds so that the precursor is adsorbed onto the surface of the substrate, a gas mixture of nitrogen gas(N₂) and hydrogen gas(H₂) 202″″(not shown) is supplied into the reaction chamber for the time duration between 0.1 and 10 seconds in order to purge the ruthenium precursor gas un-adsorbed onto the surface of the substrate and remaining in the reaction chamber space, and while the gas mixture of nitrogen gas(N₂) and hydrogen gas(H₂) 204″″(not shown) is continuously flown through the reaction chamber, plasma is generated 216″″(not shown) in the reaction chamber by applying RF power in the reaction chamber for the duration between 0.02 and 10 seconds to deposit a ruthenium thin film on the surface of the substrate. After the plasma generation period 216″″, an inert gas is supplied(not shown) to the reaction chamber to purge the reaction chamber. Alternatively, a gas mixture of nitrogen gas(N₂) and hydrogen gas(H₂)(not shown) is also used for purging the reaction chamber after the plasma generation period 216″″. The above process steps are repeated until a ruthenium thin film is formed to a desired thickness.

### EMBODIMENT 5

As another alternative process yet according to the present invention, plasma-activated ammonia gas is used in order to deposit ruthenium thin film in a reaction chamber by using a PEALD apparatus. Referring to FIG. 4, the ruthenium precursor Ru(EtCp)₂ is supplied into the reaction chamber 400 so that the ruthenium precursor is adsorbed onto the surface of the substrate in the reaction chamber, an inert gas 402 is supplied into the reaction chamber to purge the ruthenium precursor gas un-adsorbed onto the surface of the substrate and remaining in the reaction chamber space, and the plasma-activated ammonia gas 408 is supplied into the reaction chamber so that a reaction between the ruthenium precursor adsorbed onto the surface of the substrate in the reaction chamber and the plasma-activated ammonia gas takes place in the reactor, thereby a ruthenium thin film is deposited on the surface of the substrate, and thereafter, an inert gas 412 is used for purging the reaction chamber. The sequence of these process steps is repeated until a ruthenium layer to a desired thickness is formed.

### EMBODIMENT 6

As yet another alternative process yet according to the present invention, in order to deposit a ruthenium thin film, plasma-activated gas mixture of nitrogen gas(N₂) and hydrogen gas(H₂) is used as a reactant gas. Under the same process conditions described in Embodiment 1 above, referring to FIG. 5, the ruthenium precursor Ru(EtCp)₂ is supplied into the reaction chamber 500 so that the ruthenium precursor is adsorbed onto the surface of the substrate in the reaction chamber, an inert gas 502(not shown) is supplied into the reaction chamber to purge the ruthenium precursor gas un-adsorbed onto the surface of the substrate and remaining in the reaction chamber space, the plasma-activated gas mixture of nitrogen(N₂) and Hydrogen(H₂) 508 is supplied into the reaction chamber so that a reaction between the ruthenium precursor adsorbed onto the surface of the substrate and the plasma-activated gas mixture of nitrogen gas(N₂) and hydrogen gas(H₂) takes place, thereby a ruthenium thin film is deposited on the surface of the substrate, and thereafter, an inert gas 512 is supplied into the reaction chamber to purge the reaction chamber. The sequence of the above process steps is repeated until a ruthenium layer to a desired thickness is formed. Some of the key points and results are illustratively explained in the following.

As shown in Table 1 below, the density of the ruthenium film deposited using the PEALD method according to the present invention, measured at 12.03 g/cm³, is proved to be denser than the ruthenium film deposited using a CVD method, measured at 6.6 g/cm³, and a conventional thermal ALD method measured at 8.7 g/cm³.

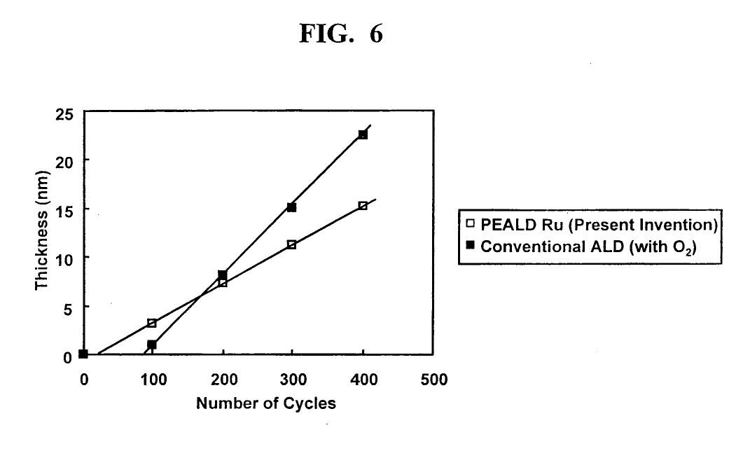

The changes of the ruthenium thin film thickness as a function of the number of film deposition cycles for depositing ruthenium thin films using a PEALD method according to the present invention and for depositing ruthenium thin film deposition using conventional thermal ALD method are illustrated in the graph in FIG. 6, where the substrates used for this comparison are thermally grown SiO₂ wafers.

FIG. 6 also illustrates that the ruthenium thin film deposition rate per PEALD gas supply cycle of the PEALD method according to the present invention is slower than the ruthenium thin film deposition rate for conventional thermal ALD method, and further that the deposition incubation period for the PEALD method is reduced, whereby such reduction is due most likely to the denser nucleation at the initial phase of the thin film formation as evidenced in FIG. 6. On the other hand, the PEALD method using plasma according to the present invention takes less number of deposition cycles compared to the method of conventional thermal ALD for depositing ruthenium thin films of thickness of merely 5 nm or less.

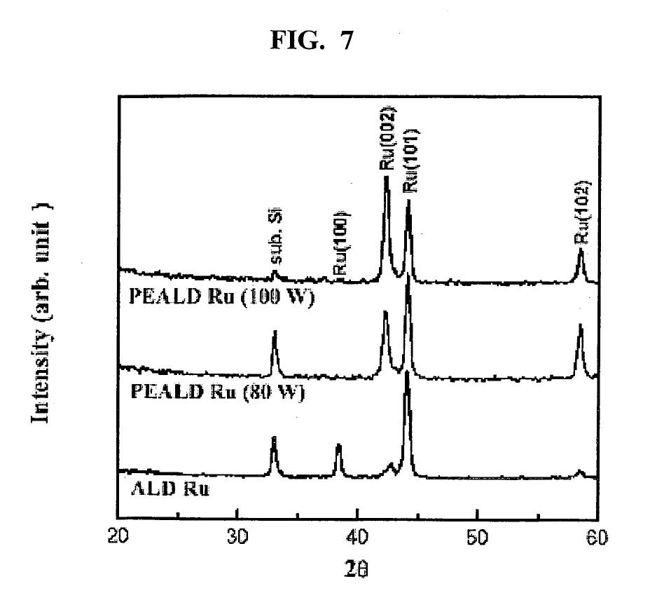

The results of the X-ray diffraction analyses of the ruthenium thin films are comparatively shown in FIG. 7, where the top curve is the result of a ruthenium thin film deposited using a PEALD method with the RF power level of 100 W, the middle curve is the result of a ruthenium thin film deposited using a PEALD method with the RF power level of 80 W and the bottom curve is the result of a ruthenium thin film deposited by conventional thermal ALD method, of which the top and the middle curves are the results of Embodiment 1 according to the present invention. The results shown in FIG. 7 show that the crystal structure of the ruthenium thin film deposited according to the deposition method of the present invention is in the form of the hexagonal close packed structure with the preferred orientation of (002) plane(top and middle curves), whereas the result of conventional thermal ALD method (bottom curve) displays a crystal structure with random orientations. Furthermore, such unique characteristics of the hexagonal close packed structure is noticeably evidenced as the RF power is increased, meaning that when the copper layer is subsequently deposited on top of the ruthenium thin film, the characteristics of the heteroepitaxial growth of copper in the orientation of (111) plane of the copper crystal structure is improved, thereby the property of the orientation of the crystal structure of copper has a tendency of reducing the phenomenon of electromigration, and thus such characteristics is beneficial for producing more reliable copper interconnections for fabricating very high density semiconductor devices. Therefore, the use of the ruthenium thin film deposited according to the present invention as either a diffusion barrier layer or an adhesion layer is an added benefit in fabricating very high density semiconductor devices.

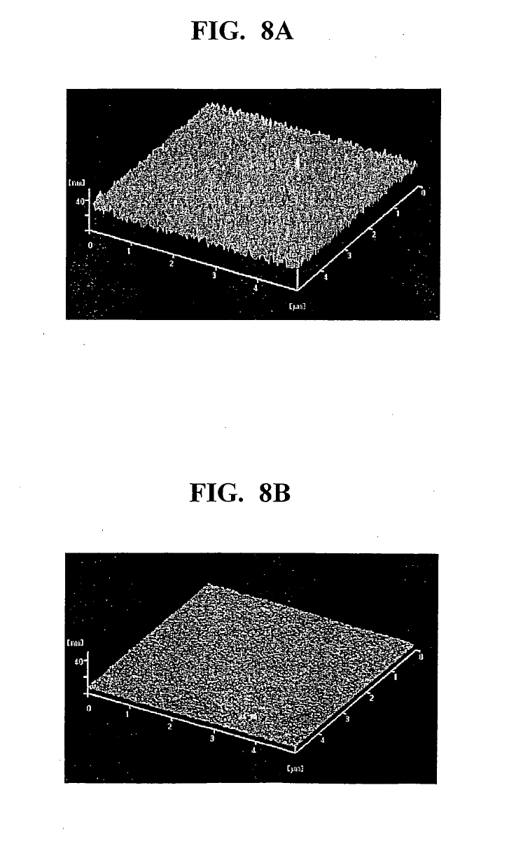

FIGS. 8A and 8B show the surface roughness of the ruthenium thin films deposited by the PEALD method and conventional thermal ALD method. The surface roughness of the ruthenium thin film formed by conventional thermal ALD method is shown in FIG. 8A, where the surface roughness is measured at about 3.1 nm in root-mean-square(rms). On the other hand, shown in FIG. 8B is the surface roughness of the ruthenium thin film deposited by the PEALD method according to the present invention, where the surface roughness is measured at about 0.7 in rms, indicating that the ruthenium thin film deposited by the present invention is much smoother than the ruthenium film deposited by conventional thermal ALD method. This result is consistent with the phenomenon of reduced deposition incubation period, due most likely to the denser nucleation at the initial phase of the ruthenium thin film formation as described previously. This is an indication that the use of the ruthenium thin film deposited by the present invention is much more beneficial in lowering the surface resistivity, in turn surface electrical resistance, compared to the use of the ruthenium thin film deposited by conventional thermal ALD method, when the ruthenium thin film in thickness in the range of 2 nm and 3 nm is to be deposited for the applications of forming either diffusion barrier layers or adhesion layers or both.

TABLE 1

| Deposition | Ru Film | Ru Film | Ru Film by PEALD |
|---|---|---|---|
| Method | by CVD | by Thermal ALD | (Present Invention) |
| Density | 6.6 | 8.7 | 12.03 |
| [g/cm3] | | | |

As described previously, ammonia gas(NH₃) or a gas mixture of nitrogen gas(N₂) and hydrogen gas(H₂) can be used as an inert gas to purge the reaction chamber, thereby the gas supply period can be shortened and also the switching to the inert gas supply is eliminated. FIGS. 3 and 5 illustrate.two examples of shortening the PEALD process cycle by taking advantage of using only one gas as a reactant gas as well as a purge gas according to the present invention, where ammonia gas(NH₃) and a gas mixture of nitrogen gas(N₂) and hydrogen gas(H₂) are, respectively, used as a reactant gas as well as a purge gas according to the present invention, thereby eliminating the use of purge gas. The use of ammonia gas(NH₃) or a gas mixture of nitrogen gas(N₂) and hydrogen gas(H₂) as a reactant gas as well as a purge gas not only shortens the process cycles but also simplify the process steps since plasma is generated while only one gas, ammonia gas or the gas mixture of nitrogen gas and hydrogen gas, is being flown into the reaction chamber during the deposition process.

The ruthenium thin film deposition process cycle is further reduced or shortened by supplying a plasma-activated reactant gas as illustrated in FIG. 5 according to the present invention.

The procedures and results presented here are merely illustrative examples of carrying out the implementation of the underlying ideas and procedures of the present invention. Five exemplary embodiments given above are neither intended for exhaustively illustrating the basic ideas and procedures nor limiting the scope of the present invention. Furthermore, those who are familiar with the art related to the present invention should be able to easily derive variations and modifications of the underlying ideas and procedures of the present invention disclosed herein.

### INDUSTRIAL APPLICABILITY

According to the present invention, stable, highly pure and uniform ruthenium thin films with low resistivity are deposited using a ruthenium precursor and plasma ammonia and by using a PEALD apparatus and the method thereof at the temperature below 400° C. Such ruthenium thin films are essential for using as diffusion barrier layers as well as adhesion layers for constructing the interconnecting copper wires in fabricating extremely high density semiconductor devices. Also, such ruthenium thin films deposited according to the present invention are advantageous over the ruthenium thin film deposited by conventional thermal ALD method because of the improved electrical resistivity due to the reduced surface electron scattering caused by much smoother surface of the ruthenium thin film deposited according to the present invention.

What is claimed is:

1. A method of depositing a ruthenium(Ru) thin film on a substrate in a reaction chamber by using a plasma enhanced atomic layer deposition(PEALD) method, comprising;
supplying a ruthenium precursor gas having the structure of the form Ru(XaXb) into the reaction chamber so that the ruthenium precursor gas is adsorbed onto the surface of the substrate, where Xa and Xb are, respectively, any one of cyclopentadienyl(Cp), methylcyclopentadienyl (MeCp), ethylcyclopentadiennyl(EtCp) and isopropylcyclopentadienyl(i-PrCp); and
generating ammonia plasma in the reaction chamber by supplying ammonia gas into the reaction chamber and then generating plasma in the reaction chamber or supplying plasma-activated ammonia gas into the reaction chamber so that a reaction between the ruthenium precursor adsorbed onto the surface of the substrate and the ammonia gas activated by plasma takes place in the reaction chamber, thereby a ruthenium thin film is deposited on the surface of the substrate.

2. The method of claim 1, further comprising:
repeating the process steps until a ruthenium thin film is formed to a desired thickness with or without purging the reaction chamber with an inert gas after supplying the ruthenium precursor gas.

3. The method of claim 2, wherein the inert gas is ammonia gas(NH₃) without activation by plasma.

4. The method of claim 1, further comprising:
repeating the process steps until a ruthenium thin film is formed to a desired thickness with or without purging the reaction chamber with an inert gas after the plasma period.

5. The method of claim 4, wherein the inert gas is ammonia gas(NH₃) without activation by plasma.

6. The method of claim 1, wherein before a ruthenium precursor gas is supplied to the reaction chamber the reaction chamber is purged with an inert gas.

7. The method of claim 6, wherein the inert gas is ammonia gas(NH₃) without activation by plasma.

8. The method of claim 1, wherein after a ruthenium precursor is supplied to the reaction chamber, ammonia gas(NH₃) is supplied to the reaction chamber and at the same time plasma is generated in synchronization with the supply period of the ammonia gas(NH₃) so that a reaction between the ruthenium precursor adsorbed onto the surface of the substrate and the ammonia gas(NH₃) activated by plasma takes place, thereby a ruthenium thin film is deposited on the substrate.

9. The method of claim 1, wherein the inside temperature of the reaction chamber is in the range from 100° C. to 400° C.

10. The method of claim 1, wherein the ruthenium precursor is Ru(EtCp)₂, the inside temperature of the reaction chamber is in the range from 100° C. to 400° C., the reaction chamber pressure is in the range from 0.01 to 50 torr, ammonia gas(NH₃) is supplied into the reaction chamber and then plasma is generated in the reaction chamber so that a reaction between the ruthenium precursor adsorbed onto the surface of the substrate and the ammonia gas(NH₃) activated by plasma takes place in the reaction chamber, thereby a ruthenium thin film is deposited on the substrate.

11. The method of claim 10, wherein the ruthenium precursor gas is supplied into the reaction chamber for the time duration between 0.02 and 20 seconds.

12. The method of claim 10, wherein after supplying the ruthenium precursor gas to the reaction chamber, the reaction chamber is purged with an inert gas for the time duration between 0.1 and 10 seconds.

13. The method of claim 12, wherein the inert gas is ammonia gas(NH₃) without activation by plasma.

14. The method of claim 10, wherein plasma is generated in the reaction chamber for the time duration between 0.02 and 10 seconds.

15. A method of depositing a ruthenium thin film on the surface of a substrate in a reaction chamber by using a plasma enhanced atomic layer deposition(PEALD) method, comprising;
supplying a ruthenium precursor gas having the structure of the form Ru(XaXb) into the reaction chamber so that the ruthenium precursor gas is adsorbed onto the surface of the substrate, where Xa and Xb are, resprctively, any one of cyclopentadienyl(Cp), methylcyclopentadienyl (MeCp), ethylcyclopentadiennyl(EtCp) and isopropylcyclopentadienyl(i-PrCp); and
generating the mixed gas plasma of nitrogen gas(N₂) and hydrogen gas(H₂) in the reaction chamber by supplying a gas mixture of nitrogen gas(N₂) and hydrogen gas(H₂) to the reaction chamber and then generating plasma in the reaction chamber or supplying plasma-activated gas mixture of nitrogen gas(N₂) and hydrogen gas(H₂) into the reaction chamber so that a reaction between the ruthenium precursor adsorbed onto the surface of the substrate and the gas mixture activated by plasma takes place in the reaction chamber, thereby a ruthenium thin film is deposited on the substrate.

16. The method of claim 15, further comprising:
repeating the process steps until a ruthenium thin film is formed to a desired thickness with or without purging the reaction chamber with an inert gas after the ruthenium precursor gas is supplied.

17. The method of claim 16, wherein the purge gas is the gas mixture of nitrogen gas(N₂) and hydrogen gas(H₂) without activation by plasma.

18. The method of claim 15, further comprising:
repeating the process steps until a ruthenium thin film is formed to a desired thickness with or without purging the reaction chamber with an inert gas after the plasma generation period.

19. The method of claim 18, wherein the purge gas is the gas mixture of nitrogen gas(N₂) and hydrogen gas(H₂) without activation by plasma.

20. The method of claim 15, wherein a gas mixture of nitrogen gas(N₂) and hydrogen gas(H₂) is supplied to the reaction chamber and at the same time plasma is generated in synchronization with the supply period of the gas mixture of nitrogen gas(N₂) and hydrogen gas(H₂).

21. The method of claim 15, wherein the inside temperature of the reaction chamber is in the range from 100° C. to 400° C.

22. The method of claim 15, wherein the ruthenium precursor gas is Ru(EtCp)₂, the inside temperature of the reaction chamber is in the range from 100° C. to 400° C., the reaction chamber pressure is in the range from 0.01 to 50 torr, a gas mixture of nitrogen gas(N₂) and hydrogen gas(H₂) is supplied into the reactor and then plasma is generated in the reaction chamber so that a reaction between the ruthenium precursor adsorbed onto the surface of the substrate and the gas mixture of nitrogen gas(N₂) and hydrogen gas(H₂) activated by plasma takes place in the reaction chamber, thereby a ruthenium thin film is deposited on the substrate.

23. The method of claim 22, wherein the ruthenium precursor gas is supplied into the reaction chamber for the time duration between 0.02 and 20 seconds.

24. The method of claim 22, wherein after supplying the ruthenium precursor gas into the reaction chamber, the reaction chamber is purged with an inert gas for the time duration between 0.1 and 10 seconds.

25. The method of claim 24, wherein the purge gas is the gas mixture of nitrogen gas(N₂) and hydrogen gas(H₂) without activation by plasma.

26. The method of claim 22, wherein plasma is generated in the reaction chamber for the time duration between 0.02 and 10 seconds.

27. A method of depositing a ruthenium(Ru) thin film on the surface of a substrate in a reaction chamber by using a plasma enhanced atomic layer deposition(PEALD) method, comprising;
supplying a ruthenium precursor gas having the structure of the form Ru(XaXb) into the reaction chamber so that the ruthenium precursor gas is adsorbed onto the surface of the substrate, where Xa and Xb are, respectively, any one of cyclopentadienyl(Cp), methylcyclopentadienyl (MeCp), ethylcyclopentadiennyl(EtCp) and isopropylcyclopentadienyl(i-PrCp); and
supplying ammonia gas(NH₃) into the reaction chamber to purge the reaction chamber; and
generating plasma in the reaction chamber while the ammonia gas(NH₃) is continuously flown through the reaction chamber so that a reaction between the ruthenium precursor adsorbed onto the surface of the substrate and the ammonia gas(NH₃) activated by plasma takes place in the reaction chamber, thereby a ruthenium thin film is deposited on the surface of the substrate.

28. The method of claim 27, wherein the inside temperature of the reaction chamber is between 100° C. and 400° C.

29. The method of claim 27, further comprising:
repeating the process steps until a ruthenium thin film is formed to a desired thickness with or without purging the reaction chamber after the plasma generation period either by continuously flowing ammonia gas through the reaction chamber or by supplying an inert gas into the reaction chamber.

30. A method of depositing a ruthenium(Ru) thin film on the surface of a substrate in a reaction chamber by using a plasma enhanced atomic layer deposition(PEALD) method, comprising;
supplying a ruthenium precursor gas having the structure of the form Ru(XaXb) into the reaction chamber so that the ruthenium precursor gas is adsorbed onto the surface of the substrate, where Xa and Xb are, resprctively, any one of cyclopentadienyl(Cp), methylcyclopentadienyl (MeCp), ethylcyclopentadiennyl(EtCp) and isopropylcyclopentadienyl(i-PrCp); and
supplying a gas mixture of nitrogen gas(N₂) and hydrogen gas(H₂) into the reaction chamber to purge the reaction chamber; and
generating plasma in the reaction chamber while the gas mixture of nitrogen gas(N₂) and hydrogen gas(H₂) is continuously flown through the reaction chamber so that a reaction between the ruthenium precursor adsorbed onto the surface of the substrate and the gas mixture of nitrogen gas(N₂) and hydrogen gas(H₂) activated by plasma takes place in the reaction chamber, thereby a ruthenium thin film is deposited on the surface of the substrate.

31. The method of claim 30, wherein the inside temperature of the reaction chamber is between 100° C. and 400° C.

32. The method of claim 30, further comprising:
repeating the process steps until a ruthenium thin film is formed to a desired thickness with or without purging the reaction chamber after the plasma generation period either by continuously flowing the gas mixture of nitrogen gas(N₂) and hydrogen gas(H₂) through the reaction chamber or by supplying an inert gas into the reaction chamber.
